(19) United States
(12) Patent Application Publication
(10) Pub. No.: US 2024/0038533 A1
(43) Pub. Date: Feb. 1, 2024

(54) SUBSTRATE PROCESSING METHOD AND SUBSTRATE PROCESSING APPARATUS

(71) Applicant: Tokyo Electron Limited, Tokyo (JP)

(72) Inventors: Hiroki TADATOMO, Kumamoto (JP); Makoto MURAMATSU, Kumamoto (JP); Kenichi UEDA, Kumamoto (JP); Arnaud Alain Jean DAUENDORFFER, Kumamoto (JP); Tomoya ONITSUKA, Kumamoto (JP); Keisuke YOSHIDA, Kumamoto (JP)

(21) Appl. No.: 18/022,213

(22) PCT Filed: Aug. 10, 2021
(86) PCT No.: PCT/JP2021/029557

§ 371 Date: Feb. 20, 2023

(30) Foreign Application Priority Data
Aug. 20, 2020 (JP) 2020-139405

(51) Int. Cl. H01L 21/027; H01L 21/311; H01L 21/687; H01L 21/67

(52) U.S. Cl. CPC H01L 21/0274; H01L 21/31144; H01L 21/68742; H01L 21/67098

(57) ABSTRACT

The present disclosure provides a substrate processing method and a substrate processing apparatus which are effective in preventing pattern collapse of an uneven pattern. The substrate processing method according to an exemplary embodiment includes replacing a liquid in a recess of a substrate having an uneven pattern of a negative type resist including a metal formed on a surface of the substrate with a solid-state stiffener, and subjecting the substrate to a molecular weight reduction processing that reduces the number of intermolecular bonds contained in the solid-state stiffener while maintaining the solid-state stiffener in a solid state.

This is a National Phase Application filed under 35 U.S.C. 371 as a national stage of PCT/JP2021/029557, filed Aug. 10, 2021, an application claiming the benefit of Japanese Application No. 2020-139405, filed Aug. 20, 2020, the content of each of which is hereby incorporated by reference in its entirety.

### TECHNICAL FIELD

The present disclosure relates to a substrate processing method and a substrate processing apparatus.

### BACKGROUND

Patent Document 1 discloses a substrate drying method (substrate processing method) for drying a substrate by removing a liquid on the substrate having an uneven pattern formed on the surface thereof.

### PRIOR ART DOCUMENT

### Patent Document

Patent Document 1: Japanese Laid-Open Patent Publication No. 2012-243869

The present disclosure provides a substrate processing method and a substrate processing apparatus which are effective in preventing pattern collapse of an uneven pattern.

### SUMMARY

A substrate processing method according to an aspect of the present disclosure includes replacing a liquid in a recess of a substrate having an uneven pattern of a negative type resist including a metal formed on a surface thereof with a solid-state stiffener and subjecting the substrate to a molecular weight reduction processing that reduces the number of intermolecular bonds contained in the stiffener while maintaining the stiffener in a solid state.

According to the present disclosure, there are provided a substrate processing method and a substrate processing apparatus which are effective in preventing pattern collapse of an uneven pattern.

### BRIEF DESCRIPTION OF DRAWINGS

FIG. 1 is a schematic diagram illustrating a schematic configuration of a substrate processing system.

FIG. 2 is a schematic diagram illustrating an internal configuration of a coating/developing apparatus.

FIG. 3 is a schematic diagram illustrating a configuration of a developing unit.

FIG. 4 is a schematic diagram illustrating a configuration of an irradiation unit.

FIG. 5 is a schematic diagram illustrating a configuration of a plasma processing apparatus.

FIG. 6 is a block diagram illustrating a functional configuration of a control device.

FIG. 7 is a block diagram illustrating a hardware configuration of the control device.

FIG. 8 is a flowchart illustrating an example of a developing procedure.

FIGS. 9A to 9D are schematic diagrams illustrating the state inside a recess in an example of a developing procedure.

FIG. 10 is a diagram illustrating an example of the chemical formula of a polymer included in a stiffener.

FIG. 11A is a schematic diagram illustrating how exposure is performed in an example of exposure, and FIG. 11B is a schematic diagram illustrating an example of a developing procedure according to a modification.

FIGS. 12A and 12B are schematic diagrams illustrating an example of a developing procedure.

FIG. 13 is a schematic diagram illustrating an example of a developing procedure.

FIG. 14 is a schematic diagram illustrating another example of a developing procedure according to a modification.

### DETAILED DESCRIPTION

Hereinafter, various exemplary embodiments will be described. In the description, the same reference numerals will be given to the same elements, or elements having the same functions, and redundant descriptions thereof will be omitted.

### [Substrate Processing System]

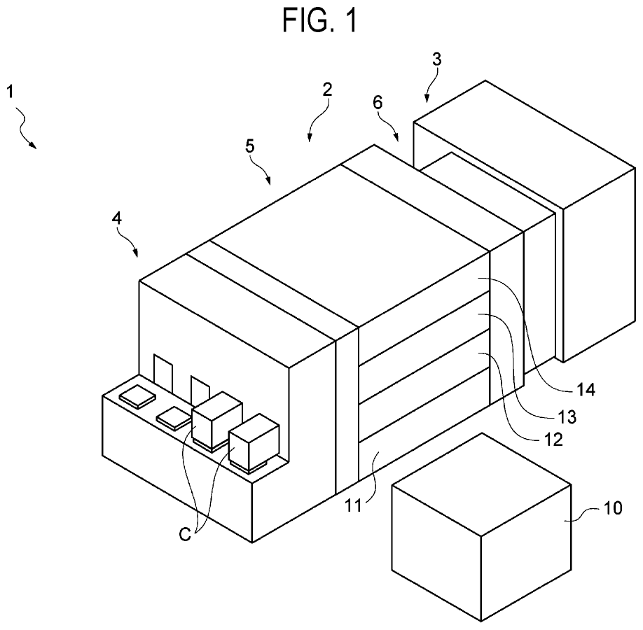

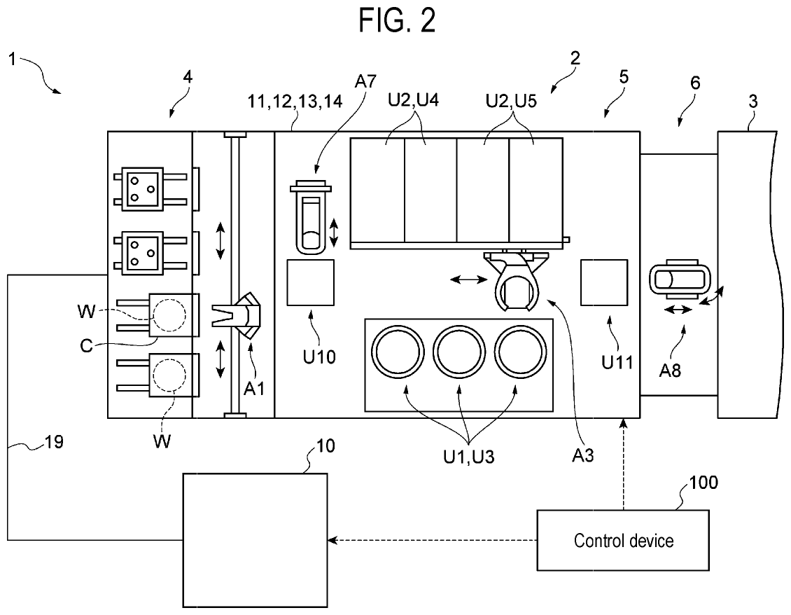

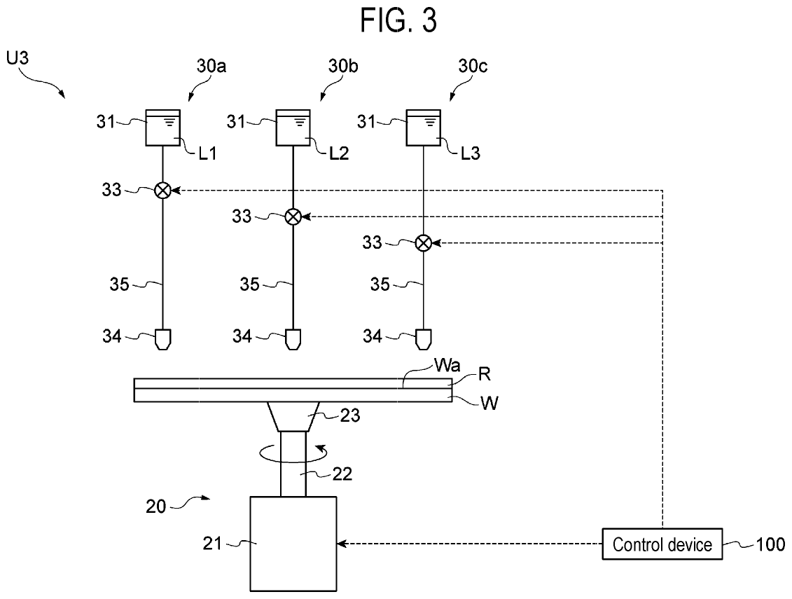

First, a schematic configuration of a substrate processing system 1 (substrate processing apparatus) will be described with reference to FIGS. 1 and 2. The substrate processing system 1 is a system that forms a photosensitive film on a substrate, exposes the photosensitive film, and develops the photosensitive film. The substrate as a processing target is, for example, a semiconductor wafer W. The photosensitive film is, for example, a resist film. The substrate processing system 1 includes a coating/developing apparatus 2, an exposure apparatus 3, a plasma processing apparatus 10, and a control device 100. The exposure apparatus 3 is an apparatus that exposes a resist film (photosensitive film) formed on the wafer W (substrate). Specifically, the exposure apparatus 3 irradiates an exposure target portion of the resist film with exposure energy rays by a method such as liquid immersion exposure. The coating/developing apparatus 2 applies a resist (chemical solution) onto the surface of the wafer W (substrate) to form the resist film before exposure by the exposure apparatus 3. Further, the coating/developing apparatus 2 develops the resist film after exposure. The plasma processing apparatus 10 etches a surface Wa (see FIG. 3) of the wafer W using a plasma after developing of the resist film. For example, the plasma processing apparatus 10 etches the wafer W using a resist pattern, formed by developing the resist film, as a mask.

### (Coating/Developing Apparatus)

As illustrated in FIGS. 1 and 2, the coating/developing apparatus 2 (substrate processing apparatus) includes a carrier block 4, a processing block 5, and an interface block 6.

The carrier block 4 introduces the wafer W into the coating/developing apparatus 2 and leads the wafer W out of the coating/developing apparatus 2. For example, the carrier block 4 is capable of supporting a plurality of carriers C for the wafer W, and incorporates a transfer device A1 including a transfer arm. The carrier C accommodates, for example, a plurality of circular wafers W. The transfer device A1 takes out the wafer W from the carrier C to transfer it to the processing block 5, and receives the wafer W from the processing block 5 to return it into the carrier C. The processing block 5 includes a plurality of processing modules 11, 12, 13 and 14.

The processing module 11 incorporates a coating unit U1, a thermal processing unit U2, and a transfer device A3 that transfers the wafer W to these units. The processing module 11 forms a lower layer film on the surface of the wafer W by the coating unit U1 and the thermal processing unit U2. The coating unit U1 applies a processing liquid for lower layer film formation onto the wafer W. The thermal processing unit U2 performs various types of thermal processing accompanied by formation of the lower layer film.

The processing module 12 incorporates the coating unit U1, the thermal processing unit U2, and the transfer device A3 that transfers the wafer W to these units. The processing module 12 forms a resist film on the lower layer film by the coating unit U1 and the thermal processing unit U2. The coating unit U1 applies a resist onto the lower layer film as a processing liquid for resist film formation. The thermal processing unit U2 performs various types of thermal processing accompanied by formation of the resist film. Thus, the resist film is formed on the surface of the wafer W.

The processing module 13 incorporates the coating unit U1, the thermal processing unit U2, and the transfer device A3 that transfers the wafer W to these units. The processing module 13 forms an upper layer film on the resist film by the coating unit U1 and the thermal processing unit U2. The coating unit U1 applies a processing liquid for upper layer film formation onto the resist film. The thermal processing unit U2 performs various types of thermal processing accompanied by formation of the upper layer film.

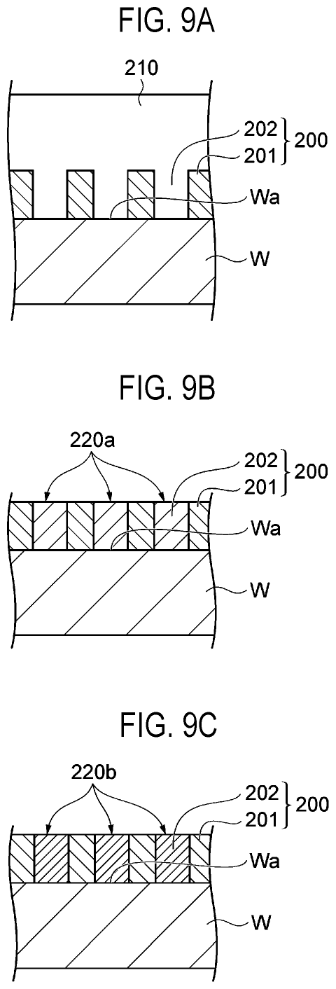

The processing module 14 incorporates a developing unit U3, a thermal processing unit U4, an irradiation unit U5, and the transfer device A3 that transfers the wafer W to these units. The processing module 14 performs a series of processing including developing of the resist film after exposure by the developing unit U3, the thermal processing unit U4, and the irradiation unit U5. The developing unit U3 partially removes the resist film (performs developing) by applying (supplying) a developing liquid onto the surface of the wafer W which is completely exposed. In other words, the developing unit U3 forms a resist pattern, which is an uneven pattern, on the surface of the wafer W. The developing unit U3 supplies a rinse liquid to the surface of the wafer W in order to wash away the developing liquid. Further, the developing unit U3 replaces the rinse liquid in a recess of the resist pattern with a processing liquid, and then forms a stiffener in the recess (see FIG. 9B). The thermal processing unit U4 performs various types of thermal processing accompanied by developing. Specific examples of the thermal processing accompanied by developing may include heating before developing (post exposure bake (PEB)), heating after developing (post bake (PB)), and the like. The irradiation unit U5 has a function of irradiating the surface of the wafer W with energy rays, and performs part of a processing for removing the rinse liquid.

A shelf unit U10 is provided in the processing block 5 on the carrier block 4 side. The shelf unit U10 is partitioned into a plurality of cells arranged in the vertical direction. A transfer device A7 including a lifting arm is provided in the vicinity of the shelf unit U10. The transfer device A7 raises and lowers the wafer W between the cells of the shelf unit U10.

A shelf unit U11 is provided in the processing block 5 on the interface block 6 side. The shelf unit U11 is partitioned into a plurality of cells arranged in the vertical direction.

The interface block 6 transfers the wafer W to and from the exposure apparatus 3. For example, the interface block 6 incorporates a transfer device A8 including a transfer arm, and is connected to the exposure apparatus 3. The transfer device A8 transfers the wafer W placed on the shelf unit U11 to the exposure apparatus 3. The transfer device A8 receives the wafer W from the exposure apparatus 3 to return it to the shelf unit U11.

### (Developing Unit)

Next, an example of the developing unit U3 will be described with reference to FIG. 3. As illustrated in FIG. 3, the developing unit U3 includes a rotary holder 20 and liquid supplies 30a, 30b, and 30c (three liquid supplies).

The rotary holder 20 includes a rotary drive 21, a shaft 22, and a holding part 23. The rotary drive 21 operates based on an operation signal from the control device 100 to rotate the shaft 22. The rotary drive 21 incorporates a power source such as an electric motor, for example. The holding part 23 is provided at the distal end of the shaft 22. The wafer W is placed on the holding part 23. The holding part 23 holds the wafer W substantially horizontally, for example, by suction or the like. In this case, the rotary holder 20 rotates the wafer W about a central axis (rotational axis) perpendicular to the surface Wa of the wafer W with the substantially horizontal attitude of the wafer W. In the example of FIG. 3, the rotary holder 20 rotates the wafer W at a predetermined number of rotations in a counterclockwise direction when viewed from above.

The liquid supply 30a supplies a developing liquid L1 to the surface Wa of the wafer W. The developing liquid L1 is a chemical solution for developing a resist film R to form a resist pattern. For example, when the developing liquid L1 is supplied to the resist film R, a portion of the resist film R irradiated with exposure energy rays (an exposed region by exposure) undergoes a reaction and is removed. That is, a negative type resist pattern (resist material) may be used. The developing liquid L1 for removing the exposed region may be, for example, an organic solvent. In addition, when the developing liquid L1 is supplied to the resist film R, a portion of the resist film R that is not irradiated with exposure energy rays (a region that is not exposed by exposure) may undergo a reaction and be removed. That is, a positive type resist pattern (resist material) may be used. The developing liquid L1 for removing the unexposed region may be, for example, an alkali solution.

The liquid supply 30b supplies a rinse liquid L2 to the surface Wa of the wafer W (the resist film R formed with the resist pattern). The rinse liquid L2 may be any chemical solution (liquid) capable of washing away the developing liquid L1. For example, the rinse liquid L2 may be water (pure water). The liquid supply 30a and the liquid supply 30b constitute a developing section that develops the resist film R.

The liquid supply 30c (replacement section) supplies a processing liquid L3 to the surface Wa of the wafer W. The processing liquid L3 is a chemical solution for forming a stiffener in a recess of the resist pattern. The processing liquid L3 may be supplied to the wafer W in a liquid state, and may be a chemical solution that is dried and solidified by a predetermined processing (e.g., rotation of the wafer W). For example, the processing liquid L3 may be a chemical solution in which a polymer is dissolved in a solvent. The polymer may contain at least one of polymethyl acrylate, polymethacrylic acid, polyvinyl alcohol, ultraviolet curable resin (UV curable resin), and polymethylmethacrylate (PMMA). When polymethyl acrylate, polymethacrylic acid, or polyvinyl alcohol is used, water may be used as the solvent. When polymethyl methacrylate is used, acetone, isopropyl alcohol (IPA), methyl alcohol, ethyl alcohol, xylene, acetic acid, methyl isobutyl ketone (MIBK), methyl isobutyl carbinol (MIBC), butyl acetate, or propylene glycol methyl ether acetate (PGMEA) may be used as the solvent.

Each of the liquid supplies 30a, 30b, and 30c includes a liquid source 31, a valve 33, a nozzle 34, and a pipe 35. The liquid sources 31 of the liquid supplies 30a, 30b, and 30c supply chemical solutions to the nozzles 34 via the valves 33 and the pipes 35, respectively. The nozzles 34 of the liquid supplies 30a, 30b, and 30c are arranged respectively above the wafer W so that discharge ports thereof face the surface Wa of the wafer W. The nozzle 34 discharges the chemical solution supplied from the liquid source 31 toward the surface Wa of the wafer W. The pipe 35 interconnects the liquid source 31 and the nozzle 34. The valve 33 switches a flow path in the pipe 35 between an open state and a closed state. In addition, the developing unit U3 may include a drive mechanism (not illustrated) that reciprocates the nozzle 34 in the horizontal direction.

The thermal processing unit U4 has a configuration capable of thermally processing the wafer W, although illustration of a detailed configuration is omitted. For example, the thermal processing unit U4 includes a chamber that may be opened or closed and defines a processing space in which a thermal processing is performed, and a hot plate that is accommodated in the chamber to support and heat the wafer W. The chamber is opened or closed according to an instruction of the control device 100. The hot plate incorporates, for example, a heater, and the temperature of the hot plate is controlled by the control device 100.

### (Irradiation Unit)

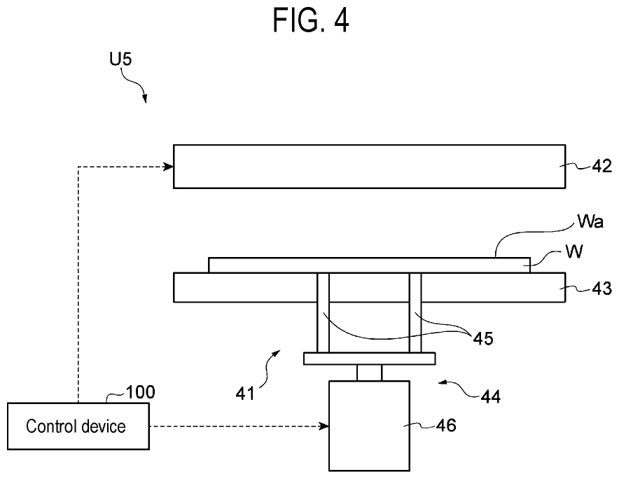

Next, an example of the irradiation unit U5 will be described with reference to FIG. 4. As illustrated in FIG. 4, the irradiation unit U5 includes an irradiator 42 (molecular weight reduction processing section).

The irradiator 42 irradiates the surface Wa (stiffener) of the wafer W with energy rays. For example, corpuscular rays such as electron beams, or electromagnetic waves may be used as the energy rays. The irradiator 42 may emit any energy rays as long as irradiation thereof may reduce the number of intermolecular bonds contained in the stiffener. For example, the irradiator 42 may emit energy rays capable of reducing the degree of polymerization of a polymer included in the stiffener. A specific example of the energy rays may be ultraviolet rays having a wavelength of 100 nm to 400 nm. The energy rays may have a wavelength of 170 nm to 180 nm. In addition, the wavelength of energy rays is not limited to the above values, and for example, the wavelength of energy rays to be used may be selected according to the kind of the stiffener.

The irradiation unit U5 emits ultraviolet rays from above by the irradiator 42 to the surface Wa of the wafer W which is horizontally supported. For example, the irradiator 42 includes a light source that emits ultraviolet rays. Specific examples of the light source may include a krypton fluoride excimer light source that emits ultraviolet rays with a wavelength of 172 nm, an argon fluoride excimer light source that emits ultraviolet rays with a wavelength of 193 nm, and a krypton chloride excimer light source that emits ultraviolet rays with a wavelength of 222 nm. The irradiator 42 is configured to emit energy rays emitted from the light source downward toward the wafer W.

### (Plasma Processing Apparatus)

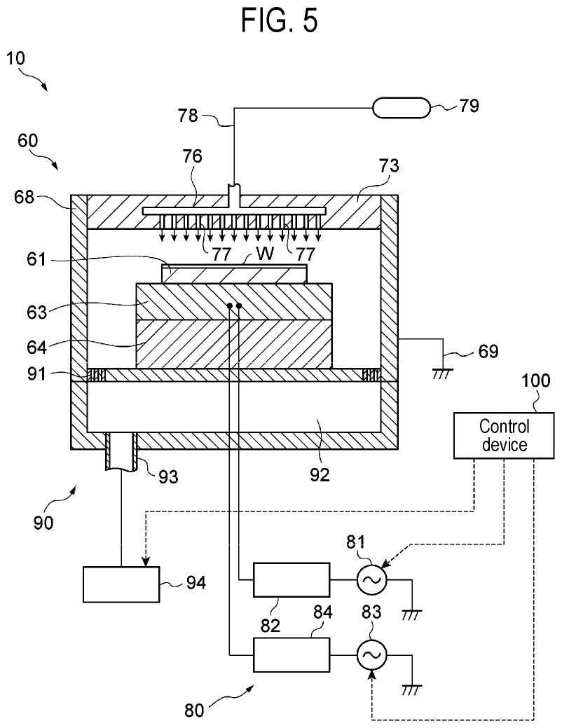

Next, an example of the plasma processing apparatus 10 will be described with reference to FIG. 5. The plasma processing apparatus 10 performs a plasma processing on the wafer W using a resist pattern as a mask. In other words, the plasma processing apparatus 10 etches a portion of the wafer W by performing etching using a plasma on the wafer W. Further, the plasma processing apparatus 10 may perform etching using a plasma on a stiffener formed in a recess of the resist pattern. In addition, in this specification, the expression “performing a plasma processing” or “performing etching using a plasma” refers to exposing at least the surface Wa of the wafer W to a gas turned in a plasma state for a predetermined period of time.

The plasma processing apparatus 10 is connected to the coating/developing apparatus 2 via a transfer mechanism 19 (see FIG. 2). The transfer mechanism 19 transfers the wafer W between the coating/developing apparatus 2 and the plasma processing apparatus 10. The plasma processing apparatus 10 is, for example, a parallel plate type apparatus. As illustrated in FIG. 5, the plasma processing apparatus 10 includes a processing section 60, a power supply section 80, and an exhaust section 90. The processing section 60 includes a processing container 68, an electrostatic chuck 61, a susceptor 63, a support 64, and an upper electrode 73.

The processing container 68 is electrically conductive and has a substantially cylindrical shape. A ground line 69 is electrically connected to the processing container 68, and the processing container 68 is grounded. The electrostatic chuck 61 and the susceptor 63 are provided within the processing container 68 to support the wafer W as a processing target. The electrostatic chuck 61 is a substantially disk-shaped member, and is formed, for example, by sandwiching an electrode for the electrostatic chuck between a pair of ceramics. The susceptor 63 functions as a lower electrode and is provided on the lower surface of the electrostatic chuck 61. The susceptor 63 is formed of a metal such as aluminum and has a substantially disc shape. The support 64 is provided on the bottom of the processing container 68, and the susceptor 63 is supported on an upper surface of the support 64. An electrode (not illustrated) is provided inside the electrostatic chuck 61, and the wafer W is attracted and held by the electrostatic chuck 61 with an electrostatic force generated by applying a DC voltage to the electrode. A coolant flow path (not illustrated) through which a coolant flows is provided inside the support 64, and the temperature of the wafer W held by the electrostatic chuck 61 is controlled by controlling the temperature of the coolant.

The power supply section 80 includes radio frequency power supplies 81 and 83 and matchers 82 and 84. The radio frequency power supply 81 for generating a plasma is electrically connected to the susceptor 63 via the matcher 82. The radio frequency power supply 81 is configured to output radio frequency power with a frequency of 27 MHz to 100 MHz, for example. Further, the internal impedance of the radio frequency power supply 81 and the load impedance are matched by the matcher 82.

The radio frequency power supply 83 is electrically connected to the susceptor 63 via the matcher 84 in order to draw ions to the wafer W by applying a bias to the wafer W. The radio frequency power supply 83 is configured to output radio frequency power with a frequency of 400 kHz to 13.56 MHz, for example. The matcher 84 matches the internal impedance of the radio frequency power supply 83 with the load impedance, similarly to the matcher 82. Operations of the radio frequency power supplies 81 and 83 and the matchers 82 and 84 are controlled by the control device 100.

The upper electrode 73 is arranged at the top of the processing container 68. The upper electrode 73 is provided so as to face the susceptor 63. The upper electrode 73 is supported on the top of the processing container 68 and is grounded via the processing container 68. A gas diffusion chamber 76 having a substantially disk shape is centrally formed inside the upper electrode 73. A plurality of gas discharge holes 77 for supplying a processing gas to the inside of the processing container 68 is formed in a lower portion of the upper electrode 73 so as to pass through the lower portion of the upper electrode 73.

A gas supply pipe 78 is connected to the gas diffusion chamber 76. A gas supply source 79 is connected to the gas supply pipe 78, as illustrated in FIG. 5, and the gas supply source 79 supplies a processing gas to the gas diffusion chamber 76 through the gas supply pipe 78. The processing gas supplied to the gas diffusion chamber 76 is introduced into the processing container 68 through the gas discharge holes 77. The processing gas supplied from the gas supply source 79 may include an inert gas. A rare gas (e.g., argon gas) or nitrogen gas may be used as the inert gas.

The exhaust section 90 is arranged below the processing container 68. The exhaust section 90 includes an exhaust port 91, an exhaust chamber 92, an exhaust pipe 93, and an exhaust device 94. The exhaust port 91 is provided in the bottom surface of the processing container 68. The exhaust chamber 92 is formed below the exhaust port 91, and the exhaust device 94 is connected to the exhaust chamber 92 via the exhaust pipe 93. By driving the exhaust device 94 (e.g., an exhaust pump), the processing container 68 may be exhausted through the exhaust port 91, and the pressure inside the processing container 68 may be reduced to a predetermined degree of vacuum.

### (Control Device)

Next, a specific configuration of the control device 100 will be exemplified. The control device 100 partially or entirely controls the substrate processing system 1. The control device 100 is configured to replace a liquid in a recess 202 of the wafer W having an uneven pattern formed on the surface Wa thereof with a solid-state stiffener 220a and to subject the wafer W with a molecular weight reduction processing that reduces the number of intermolecular bonds contained in the stiffener 220a while maintaining the stiffener 220a in a solid state. In addition, in this specification, the term “solid state” refers to a state where a main component in a chemical solution such as the processing liquid L3 is solidified to such an extent that it no longer flows after a solvent included in the chemical solution volatilizes.

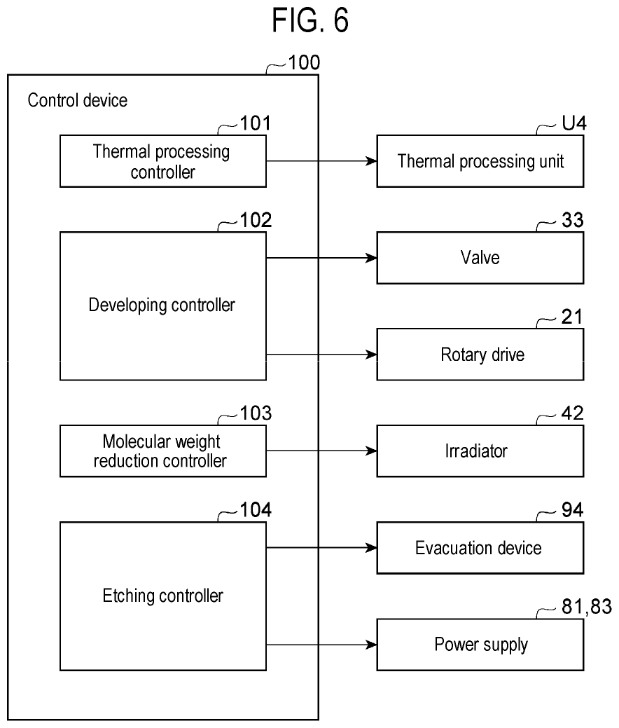

As illustrated in FIG. 6, the control device 100 includes a thermal processing controller 101, a developing controller 102, a molecular weight reduction controller 103, and an etching controller 104, as functional components (hereinafter referred to as “functional modules”). The thermal processing controller 101 controls the thermal processing unit U4. The developing controller 102 controls the valve 33 of each of the liquid supplies 30a, 30b, and 30c and the rotary drive 21 in the developing unit U3. The molecular weight reduction controller 103 controls the irradiator 42 in the irradiation unit U5. The etching controller 104 controls the exhaust device 94 and the radio frequency power supplies 81 and 83 in the plasma processing apparatus 10. A processing executed by the thermal processing controller 101, the developing controller 102, the molecular weight reduction controller 103, and the etching controller 104 corresponds to a processing executed by the control device 100. The details of processing contents executed by each functional module will be described later.

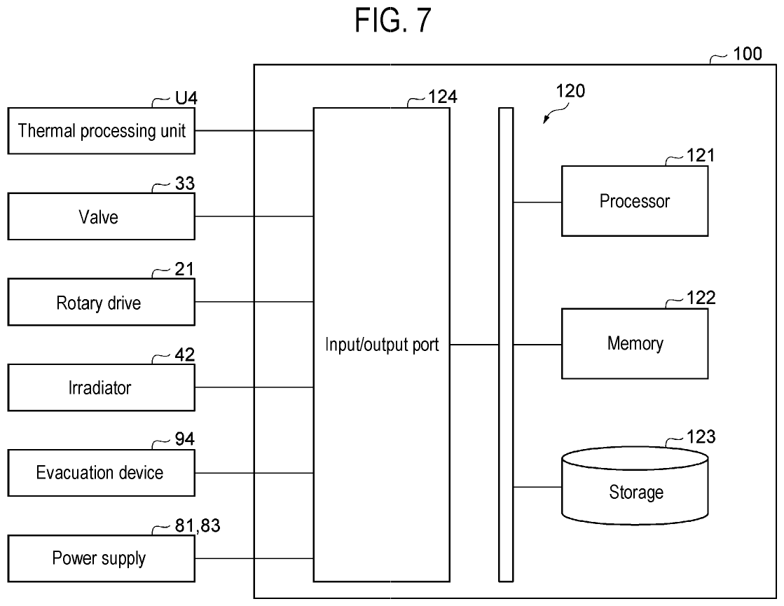

The control device 100 is constituted by one or a plurality of control computers. For example, the control device 100 includes a circuit 120 illustrated in FIG. 7. The circuit 120 includes one or a plurality of processors 121, a memory 122, a storage 123, and an input/output port 124 The storage 123 includes a non-transitory computer readable storage medium such as a hard disk, for example. The storage medium stores a program for causing the control device 100 to execute a substrate processing procedure to be described later. The storage medium may be a removable medium such as a non-volatile semiconductor memory, a magnetic disk, and an optical disk. The memory 122 temporarily stores the program loaded from the storage medium of the storage 123 and the calculation result by the processor 121. The processor 121 cooperates with the memory 122 to execute the above program, thereby configuring each functional module described above. The input/output port 124 inputs and outputs electric signals to and from a member, which is a control target, according to a command from the processor 121.

When the control device 100 is constituted with a plurality of control computers, each of the thermal processing controller 101, the developing controller 102, the molecular weight reduction controller 103, and the etching controller 104 may be realized by an individual control computer. Alternatively, each of these functional modules may be realized by a combination of two or more control computers. In these cases, the plurality of control computers may execute a substrate processing procedure to be described later in association with each other while being connected to each other so as to be able to communicate with each other. In addition, a hardware configuration of the control device 100 is not necessarily limited to configure each functional module by the program. For example, each functional module of the control device 100 may be configured by a dedicated logic circuit or an application specific integrated circuit (ASIC) integrated with the logic circuit.

### [Substrate Processing Procedure]

Next, a substrate processing procedure executed in the substrate processing system 1 will be described as an example of a substrate processing method. The control device 100 controls the substrate processing system 1 so as to execute a substrate processing including coating and developing, for example, in the following procedure. First, the control device 100 controls the transfer device A1 to transfer the wafer W in the carrier C to the shelf unit U10, and controls the transfer device A7 so as to place the wafer W in the cell for the processing module 11.

Subsequently, the control device 100 controls the transfer device A3 so as to transfer the wafer W on the shelf unit U10 to the coating unit U1 and the thermal processing unit U2 in the processing module 11. Further, the control device 100 controls the coating unit U1 and the thermal processing unit U2 so as to form a lower layer film on the surface Wa of the wafer W. After that, the control device 100 controls the transfer device A3 so as to return the wafer W on which the lower layer film is formed to the shelf unit U10, and controls the transfer device A7 so as to place this wafer W in the cell for the processing module 12.

Subsequently, the control device 100 controls the transfer device A3 so as to transfer the wafer W on the shelf unit U10 to the coating unit U1 and the thermal processing unit U2 in the processing module 12. Further, the control device 100 controls the coating unit U1 and the thermal processing unit U2 so as to form the resist film R on the lower layer film of the wafer W. After that, the control device 100 controls the transfer device A3 so as to return the wafer W to the shelf unit U10, and controls the transfer device A7 so as to place this wafer W in the cell for the processing module 13.

Subsequently, the control device 100 controls the transfer device A3 so as to transfer the wafer W on the shelf unit U10 to each unit in the processing module 13. Further, the control device 100 controls the coating unit U1 and the thermal processing unit U2 so as to form an upper layer film on the resist film R of the wafer W. After that, the control device 100 controls the transfer device A3 so as to transfer the wafer W to the shelf unit U11.

Subsequently, the control device 100 controls the transfer device A8 so as to send the wafer W accommodated in the shelf unit Ulf to the exposure apparatus 3. Then, in the exposure apparatus 3, the resist film R formed on the wafer W is subjected to exposure. After that, the control device 100 controls the transfer device A8 so as to receive the wafer W, subjected to exposure, from the exposure apparatus 3 and place this wafer W in the cell for the processing module 14 in the shelf unit U11.

Subsequently, the control device 100 controls the transfer device A3 so as to transfer the wafer W on the shelf unit U11 to the thermal processing unit U4 of the processing module 14. Then, the control device 100 performs control so as to execute a series of processing procedure (hereinafter referred to as “developing procedure”) including a thermal processing accompanied by developing, and the developing. The details of this developing procedure will be described later. By executing the developing procedure, a resist pattern is formed on the surface Wa of the wafer W. After that, the control device 100 controls the plasma processing apparatus 10 so as to perform etching using a plasma on the wafer W by using the resist pattern as a mask. The substrate processing including coating and developing is completed as described above.

### (Developing Procedure)

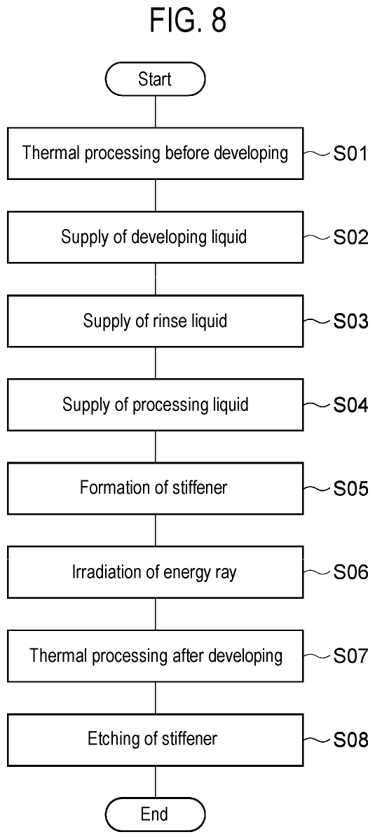

Next, an example of a developing procedure will be described with reference to FIGS. 8 to 10. FIG. 8 is a flowchart illustrating an example of a developing procedure. First, the control device 100 executes step S01. In step S01, the thermal processing controller 101 controls the thermal processing unit U4 so as to perform a thermal processing on the wafer W, subjected to exposure, at a predetermined temperature for a predetermined period of time. Then, the control device 100 controls the transfer device A3 so as to transfer the wafer W, subjected to the thermal processing before developing, to the developing unit U3.

Subsequently, the control device 100 executes step S02. In step S02, the developing controller 102 controls the developing unit U3 so as to supply the developing liquid L1 to the resist film R formed on the surface Wa of the wafer W. For example, the developing controller 102 controls the rotary drive 21 so that the wafer W rotates at a predetermined number of rotations, and opens the valve 33 of the liquid supply 30a to discharge the developing liquid L1 from the nozzle 34. Thus, the resist film R is developed, and a resist pattern 200 having a plurality of protrusions 201 and a plurality of recesses 202 is formed on the surface Wa of the wafer W (see FIG. 9A). In addition, a portion of the resist film R that is not removed (e.g., a portion that is not exposed to light during exposure) becomes the protrusion 201, and a portion of the resist film R that is removed (a space between the protrusions 201 adjacent to each other) becomes the recess 202.

Subsequently, the control device 100 executes step S03. In step S03, the developing controller 102 controls the developing unit U3 so as to supply the rinse liquid L2 to the surface Wa of the wafer W. For example, the developing controller 102 controls the rotary drive 21 so that the wafer W rotates at a predetermined number of rotations, and opens the valve 33 of the liquid supply 30b to discharge the rinse liquid L2 from the nozzle 34. As illustrated in FIG. 9A, the developing controller 102 causes the rotary drive 21 to continue rotation of the wafer W to such an extent that a part (rinse liquid 210) of the discharged rinse liquid L2 remains on the surface Wa of the wafer W, or to stop the rotation of the wafer W. At this time, the inside of each recess 202 may be fully filled with the rinse liquid 210, as in the example of FIG. 9A. That is, the height of the rinse liquid 210 (the shortest distance between the upper surface of the rinse liquid 210 and the surface Wa) may be equal to or greater than the height of the protrusion 201. In addition, the height of the rinse liquid 210 is not limited to the example of FIG. 9A, and it is only necessary that at least a part of the recess 202 is filled with the rinse liquid 210.

Subsequently, the control device 100 executes step S04. In step S04, the developing controller 102 controls the developing unit U3 so as to supply the processing liquid L3 to the wafer W with the rinse liquid 210 remaining on the surface Wa. Specifically, the developing controller 102 causes the developing unit U3 to start the supply of the processing liquid L3 to the surface Wa of the wafer W in a state where the rinse liquid 210 remains in each of the plurality of recesses 202 (e.g., in a state where the rinse liquid 210 remains in substantially all of the recesses 202). For example, the developing controller 102 controls the rotary drive 21 so that the wafer W rotates at a predetermined number of rotations, and opens the valve 33 of the liquid supply 30c, thereby causing the developing unit U3 to start the discharge of the processing liquid U3 from the nozzle 34. After that, the developing controller 102 causes the developing unit U3 to continue the rotation of the wafer W and the supply of the processing liquid L3 to the surface Wa of the wafer W for a predetermined period of time. Thus, the rinse liquid 210 on the surface Wa is pushed out of the wafer W, and the rinse liquid 210 is replaced with the processing liquid L3. For example, after replacement, the recess 202 may be fully filled with a liquid (part of the processing liquid L3). In addition, it is only necessary that at least a part of the recess 202 is filled with the processing liquid L3.

Subsequently, the control device 100 executes step S05. In step S05, the developing controller 102 controls the developing unit U3 so as to dry the processing liquid L3 filling the recess 202. For example, the developing controller 102 controls the rotary drive 21 to rotate the wafer W until the processing liquid L3, which is in a liquid state, becomes a solid state. Thus, as illustrated in FIG. 9B, the solid-state stiffener 220a is formed in the recess 202. For example, when the processing liquid L3 includes polymers, by rotating and drying the wafer W, the solvent included in the processing liquid L3 volatilizes and a large number of polymers dispersed in the solvent entangle each other. Thus, the solid-state stiffener 220a is formed in the recess 202. As described above, the liquid supply 30c and the rotary holder 20 of the developing unit U3 constitute a replacement section.

By executing steps S04 and S05, the rinse liquid 210 in the recess 202 is replaced with the solid-state stiffener 220a. At this time, as in the example of FIG. 9B, the stiffener 220a may be formed in the recess 202 so as to fill almost the entire space in the recess 202. As an example, the stiffener 220a may be formed in the recess 202 to such an extent that the height of the stiffener 220a is approximately equal to the height of the protrusion 201. In addition, the height of the stiffener 220a is not limited to the example of FIG. 9B, and it is only necessary that at least a part of the recess 202 is filled with the stiffener 220a. Further, the stiffener 220a may be formed to a height exceeding the height of the protrusion 201 (the depth of the recess 202). After executing step S05, the control device 100 controls the transfer device A3 so as to transfer the wafer W in which the stiffener 220a is formed in the recess 202 to the irradiation unit U5.

Subsequently, the control device 100 executes step S06. In step S06, the molecular weight reduction controller 103 controls the irradiation unit U5 so as to irradiate the stiffener 220a with energy rays. For example, the molecular weight reduction controller 103 controls the irradiator 42 so as to irradiate the entire surface Wa of the wafer W with energy rays. The kind of energy rays may be determined according to the kind of the processing liquid L3 (the kind of a polymer included in the stiffener 220a). By irradiating the stiffener 220a with energy rays, the number of intermolecular bonds contained in the stiffener 220a is reduced while the stiffener 220a is maintained in a solid state (the stiffener 220a does not become a liquid state). For example, when the stiffener 220a includes a polymer, the degree of polymerization of the polymer is reduced. As an example, each polymer included in the stiffener 220a may be decomposed into a plurality of polymers having a smaller degree of polymerization (e.g., several tens to several hundreds) than the degree of polymerization of the polymer (e.g., several thousands to several tens of thousands). In addition, each polymer included in the stiffener 220a may be decomposed into a plurality of monomers having one structural unit, a plurality of dimers having two structural units, or a plurality of trimers having three structural units.

In this way, the molecular weight reduction controller 103 irradiates the stiffener 220a with energy rays, thereby subjecting the water W to a molecular weight reduction processing that reduces the number of intermolecular bonds (e.g., the degree of polymerization) included in the stiffener 220a while maintaining the stiffener 220a in a solid state. Thus, as illustrated in FIG. 9C, the stiffener 220a subjected to the molecular weight reduction processing (hereinafter referred to as “stiffener 220b”) is formed in the recess 202. When performing the molecular weight reduction processing, the molecular weight reduction controller 103 may reduce the number of intermolecular bonds contained in the stiffener 220a up to a level at which the stiffener 220b is more susceptible (becomes easier) to sublimate than the resist pattern 200 (protrusion 201).

Here, the term “sublimation” in this specification means that the stiffener 220b transitions from a solid state to a gaseous state without going through a liquid state. This “sublimation” also includes a transition from a solid state to a gaseous state accompanied by a chemical change of the stiffener 220b, in addition to a state change from a solid state to a gaseous state (a change from a solid phase to a gaseous phase). For example, the transition from a solid state to a gaseous state accompanied by a chemical change includes etching the stiffener 220b by subjecting the stiffener 220b to etching using a plasma. Here, the term “ease of sublimation” means ease of sublimation (e.g., the amount of sublimation per unit time) under an environment for sublimating the stiffener 220b. For example, a state where the stiffener 220b is more susceptible to sublimate than the resist pattern 200 refers to a state where the stiffener 220b is etched more than the resist pattern 200 under plasma processing conditions for etching the stiffener 220b.

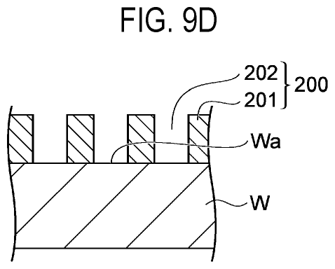

FIG. 10 illustrates how the number of bonds (degree of polymerization) in the polymer changes when the processing liquid L3 includes a polymer containing polymethyl methacrylate. The degree of polymerization of each polymer included in the stiffener 220a is indicated by “L+M+N . . . ” (L, M, and N are positive integers). When irradiating the stiffener 220a with energy rays in the irradiation unit U5, some of “C—CH2” bonds, which are main chains bonding monomers, are broken. As a result, a compound having a monomer structural unit of “L” (e.g., a polymer having a degree of polymerization of “L”), a compound having a monomer structural unit of “M”, a compound having a monomer structural unit of “N,”, and the like are formed in the stiffener 220b. For example, when a plurality of polymers having a reduced degree of polymerization are formed by irradiation with energy rays, a reduction in the degree of polymerization causes a substance to change from a stable state to a property of being more susceptible to sublimate.

After execution of step S06, the control device 100 controls the transfer device A3 so as to transfer the wafer W on which the stiffener 220b is formed to the thermal processing unit U4. Then, the control device 100 executes step S07. In step S07, the thermal processing controller 101 controls the thermal processing unit U4 so as to perform a thermal processing on the wafer W, developed by the supply of the developing liquid L1, at a predetermined temperature for a predetermined period of time. Then, the control device 100 controls the transfer device A3 so as to return the wafer W, subjected to the thermal processing after developing, to the shelf unit U10, and controls the transfer device A7 and the transfer device A1 so as to return the wafer W to the carrier C. After that, the control device 100 controls the transfer mechanism 19 so as to transfer the wafer W in the carrier C to the plasma processing apparatus 10.

Subsequently, the control device 100 executes step S08. In step S08, the etching controller 104 controls the plasma processing apparatus 10 so as to etch the stiffener 220b using a plasma. In step S08, first, the wafer W is placed on the electrostatic chuck 61 of the plasma processing apparatus 10 so that the surface Wa on which the resist pattern 200 is formed faces upward. Then, the etching controller 104 controls the plasma processing apparatus 10 so that a processing gas for plasma generation is supplied from the gas supply source 79 into the processing container 68. The processing gas may be determined, for example, according to the kind of a polymer included in the processing liquid L3. After that, the etching controller 104 controls the power supply section 80 so that the radio frequency power supply 81 and the radio frequency power supply 83 continuously apply radio frequency power to the susceptor 63 which is a lower electrode. Thus, a radio frequency electric field is created between the upper electrode 73 and the electrostatic chuck 61.

By the formation of the radio frequency electric field, a plasma of the processing gas is generated in the processing container 68, and the stiffener 220b is etched by the plasma. At this time, since the stiffener 220a is subjected to the molecular weight reduction processing to form the stiffener 220b, the stiffener 220b is more susceptible to sublimate than the resist pattern 200. Therefore, the resist pattern 200 (protrusion 201) is not etched, but the stiffener 220b is etched. Thus, as illustrated in FIG. 9D, the stiffener 220b in the recess 202 sublimates and is removed. In this way, the plasma processing apparatus 10 configures a removal section that sublimes and removes the stiffener (stiffener 220b) subjected to the molecular weight reduction processing. With the above, a series of developing procedure is completed.

The rinse liquid 210 is removed from the surface Wa of the wafer W by performing the processing of steps S04 to S08. In this developing procedure, the rinse liquid 210 discharged onto the surface Wa of the wafer W is replaced once with the stiffener 220a (stiffener 220b), and the stiffener 220b is removed (sublimated) by etching, so that the rinse liquid 210 is removed from the surface Wa of the wafer W. Considering the state inside the recess 202, after a transition from a state where it is filled with a liquid (rinse liquid 210) to a state where it is filled with a solid (stiffener 220a or 220b), the recess 202 transitions from a state where it is filled with a solid to a state where it is filled with a gas (atmosphere, etc.).

### [Effects of Embodiment]

A substrate processing method according to the present embodiment described above includes replacing a liquid in the recess 202 of the wafer W having an uneven pattern formed on the surface Wa thereof with the solid-state stiffener 220a, and subjecting the wafer W to a molecular weight reduction processing that reduces the number of intermolecular bonds contained in the stiffener 220a while maintaining the stiffener 220a in a solid state.

The substrate processing system 1 includes a replacement section that replaces a liquid in the recess 202 of the wafer W having an uneven pattern formed on the surface Wa thereof with the solid-state stiffener 220a and a molecular weight reduction processing section that subjects the wafer W to a molecular weight reduction processing that reduces the number of intermolecular bonds contained in the stiffener 220a while maintaining the stiffener 22a in a solid state.

In the substrate processing method and the substrate processing system 1, the liquid in the recess 202 of the uneven pattern is replaced with the solid-state stiffener 220a, and the stiffener 220a is subjected to the molecular weight reduction processing. By reducing the molecular weight of the stiffener 220a, the wafer W, from which the stiffener 220a (stiffener 220b) may be removed while leaving the uneven pattern, is formed. Since a substance in the recess 202 is removed by removing the stiffener 220b, a liquid such as the rinse liquid 210 is removed from the recess 202.

When removing (drying) the liquid such as the rinse liquid 210 from the inside of the recess, the wafer W is rotated at a predetermined number of rotations to centrifugally spin and remove the liquid by a centrifugal force. In this case, the recess 202 transitions from a state where it is filled with a liquid (rinse liquid) to a state where it is filled with a gas (atmosphere). In the process of this transition, there is a possibility of the collapse of the pattern (protrusion 201) due to surface tension caused by the liquid remaining in some of the plurality of recesses 202. In the substrate processing method and the substrate processing system 1 of the present embodiment, since the recess 202 does not transition from a state where it is filled with a liquid to a state where it is filled with a gas, pattern collapse due to the liquid remaining in some recesses of the uneven pattern is less likely to occur. That is, the substrate processing method and the substrate processing system 1 are effective in preventing pattern collapse.

In the above embodiment, when performing the molecular weight reduction processing, the number of intermolecular bonds contained in the stiffener 220a is reduced up to a level at which the stiffener 220b is more susceptible to sublimate than the uneven pattern. In this case, the wafer W, from which the stiffener 220b may be removed more reliably while leaving the uneven pattern, is formed.

The substrate processing method according to the above embodiment further includes sublimating and removing the stiffener (stiffener 220b) subjected to the molecular weight reduction processing. The stiffener 220b is more susceptible to sublimate than the uneven pattern since it is subjected to the molecular weight reduction processing. Therefore, it is possible to sublimate and remove the stiffener 220b while leaving the uneven pattern. In this method, when removing (drying) the liquid in the recess 202, a substance in the recess 202 transitions in the order of liquid, solid, and gas, so that it is possible to prevent pattern collapse caused by a transition from a state where the recess 202 is filled with a liquid to a state where the recess 202 is filled with a gas.

In the above embodiment, sublimating and removing the stiffener 220b includes etching the stiffener 220b using a plasma. In this case, since the stiffener 220b is subjected to the molecular weight reduction processing, it is possible to sublimate the solid-state stiffener 220b by etching using a plasma while leaving the uneven pattern. The etching of the stiffener 220b using a plasma is performed by the plasma processing apparatus 10. Therefore, the plasma processing apparatus 10 may be used not only for etching the wafer W using the resist pattern 200 as a mask, but also for etching the stiffener 220b, so that the configuration of the substrate processing system 1 may be simplified.

In the above embodiment, replacement with the stiffener 220a includes supplying the processing liquid L3 to the surface Wa of the wafer W to replace the liquid in the recess 202 with the processing liquid L3, and drying the processing liquid L3 to form the stiffener 220a in the recess 202. In this case, it is easy to transition the inside of the recess 202 from a state where it is filled with a liquid to a state where it is filled with a solid.

In the above embodiment, the uneven pattern includes the plurality of recesses 202. Supplying the processing liquid L3 to the surface Wa of the wafer W includes starting the supply of the processing liquid L3 to the surface Wa of the wafer W in a state where the liquid remains in each of the plurality of recesses 202. In this case, the possibility of the liquid remaining in some of the plurality of recesses 202 is reduced, which prevents pattern collapse caused when replacing the liquid (e.g., the rinse liquid 210) in the recess 202 with the processing liquid L3.

In the above embodiment, the stiffener 220a (processing liquid L3) includes a polymer containing at least one of polymethyl acrylate, polymethacrylic acid, polyvinyl alcohol, an ultraviolet curable resin, and polymethyl methacrylate. In this case, the degree of polymerization of the polymer included in the stiffener 220b is lower than the degree of polymerization of the polymer included in the stiffener 220a. A reduction in the degree of polymerization makes a substance more reactive, so that it is possible to react (sublimate) and remove the stiffener 220a under conditions in which the uneven pattern does not undergo a reaction.

Although it is also conceivable to supply a processing liquid including a polymer that has a low degree of polymerization and is easily reactive, such a processing liquid is in an unstable state, and it is difficult to handle the processing liquid either before or after supplying the processing liquid. In the above embodiment, it is easier to handle the processing liquid upon supply thereof by decomposing a polymer having a high degree of polymerization (e.g., a degree of polymerization of several thousands to several tens of thousands) into polymers having a low degree of polymerization (e.g., a degree of polymerization of several tens to several hundreds). Further, when drying the processing liquid, polymers having a high degree of polymerization entangle each other to form the solid-state stiffener 220a, so that it is easy to transition a substance in the recess 202 from a liquid state to a solid state. In addition, depending on the kind of a substance contained in the processing liquid, there is a possibility of a thin film being formed on the surface of the protrusion 201 to achieve a reduction in the roughness of the resist pattern 200.

Although one embodiment has been described above, the present disclosure is not necessarily limited to the above-described embodiment, and various changes are possible without departing from the gist of the present disclosure.

### (Modification 1)

In the molecular weight reduction processing, thermal energy may be applied to the wafer W, in addition to energy rays. In the processing of step S06, the control device 100 may implement the molecular weight reduction processing on the stiffener 220a by applying thermal energy to the stiffener 220a, in addition to irradiation with energy rays. For example, the molecular weight reduction controller 103 may control the irradiation unit U5 to apply thermal energy to the stiffener 220a by placing the wafer W on a hot plate 43 to be described later and heating the wafer W. In this case, the irradiation unit U5 may further include a heater 41 (molecular reduction processing section) (see FIG. 4).

The heater 41 heats the stiffener 220a formed in the recess 202 of the resist pattern 200. As the stiffener 220a is heated, the resist pattern 200 (protrusion 201) is also heated. For example, the heater 41 includes the hot plate 43 and a lifting mechanism 44. The hot plate 43 is a plate-shaped heating element for supporting the wafer W which is horizontally disposed and heating the wafer W. For example, the hot plate 43 incorporates a plurality of heaters as a heat source. A specific example of the heater may be an electric heating wire type heater or the like.

The lifting mechanism 44 raises and lowers the wafer W on the hot plate 43. For example, the lifting mechanism 44 includes a plurality of (e.g., three) lifting pins 45 and a lifting drive 46. The plurality of lifting pins 45 protrude upward so as to pass through the hot plate 43. The lifting drive 46 raises and lowers the plurality of lifting pins 45 so that the distal ends thereof protrude upward and retract relative to the hot plate 43. Thus, it is possible to raise and lower the wafer W on the hot plate 43.

The molecular weight reduction controller 103 may control the heater 41 so that the hot plate 43 heats the wafer W in a state where the lifting pins 45 are lowered by the lifting drive 46. Further, the molecular weight reduction controller 103 may control the irradiator 42 so as to irradiate the surface Wa with energy rays in a state where the wafer W is raised (brought closer to the irradiator 42) by driving the lifting drive 46. In addition, the heater 41 and the irradiator 42 may not necessarily be configured as one unit, and may be configured as units independent of each other.

### (Modification 2)

In the molecular weight reduction processing, thermal energy may be applied to the wafer W instead of energy rays. The control device 100 (molecular weight reduction controller 103) may implement the molecular weight reduction processing on the stiffener 220a by applying thermal energy to the wafer W instead of irradiating the wafer W with energy rays. In this case, the irradiator 42 may be omitted in the irradiation unit U5. Alternatively, the control device 100 may perform the molecular weight reduction processing by applying thermal energy to the stiffener 220a in the thermal processing unit U4 instead of the irradiation unit U5. In addition, the control device 100 may control the thermal processing unit U4 so as to perform a thermal processing after developing in parallel with the molecular weight reduction processing.

When thermal energy is applied to the stiffener 220a including a polymer containing polymethyl methacrylate, some of “C—CH2” bonds are broken, resulting in a reduction in the number of intermolecular bonds, as in the case of irradiation with energy rays (see FIG. 10). In this way, by applying thermal energy to form a plurality of compounds with a reduced number of intermolecular bonds, a substance changes from a stable state to a property of being more susceptible to sublimate.

In Modification 1, Modification 2, and the embodiment described above, the uneven pattern is the resist pattern 200 formed by subjecting the exposed resist film R to developing. The molecular weight reduction processing includes applying at least one of thermal energy and energy rays to the resist pattern 200 and the stiffener 220a. In this case, when the rinse liquid L2 is used to wash away the developing liquid L1 for use in developing, pattern collapse due to the removal of the rinse liquid L2 is prevented.

### (Modification 3)

In order to sublimate the stiffener, the wafer W may be placed in a depressurized space instead of or in addition to etching using a plasma. In the processing of step S08, the control device 100 may implement sublimation (evaporation) of the stiffener 220b by placing the wafer W on which the stiffener 220b is formed into the processing container 68 of the plasma processing apparatus 10 instead of etching using a plasma. That is, the control device 100 may implement sublimation of the stiffener 220b by placing the wafer W in the depressurized space. Alternatively, in addition to sublimating a portion of the stiffener 220b by placing the wafer W in the depressurized space (inside the processing container 68) of the plasma processing apparatus the control device 100 may implement sublimation of the remaining portion of the stiffener 220b by etching using a plasma. Even in this case, the plasma processing apparatus 10 may be used not only for etching the wafer W using the resist pattern 200 as a mask, but also for etching the stiffener 220b, so that the configuration of the substrate processing system 1 may be simplified.

The substrate processing system 1 may include a depressurization unit (removal section) capable of forming a depressurized space (a space in a substantially vacuum state), instead of the plasma processing apparatus 10, and the removal of the stiffener 220b may be performed in the depressurization unit. The depressurization unit may be provided in the coating/developing apparatus 2. In this case, all the above-described developing procedure may be performed in the coating/developing apparatus 2. When sublimating the stiffener 220b in the depressurized space, the control device 100 may reduce the number of intermolecular bonds (e.g., the degree of polymerization of a polymer) in the molecular weight reduction processing of step S06 so that the stiffener 220b is more susceptible than the resist pattern 200 when the wafer W is placed in the depressurized space after the molecular weight reduction processing.

In a substrate processing method according to Modification 3, sublimating and removing the stiffener 220b includes placing the wafer W in the depressurized space to sublimate the stiffener 220b. Since the stiffener 220b is subjected to the molecular weight reduction processing, it is possible to evaporate the solid-state stiffener 220b without going through a liquid state while leaving the uneven pattern by placing the wafer W in the depressurized space.

### (Modification 4)

The resist film R, which contains a cross-linking agent that promotes cross-linking in response to the irradiation of energy rays or heating in the molecular weight reduction processing, may be used. In this case, in step S06, when the entire surface Wa of the wafer W is irradiated with energy rays, or when the entire wafer W is heated, the stiffener 220a is subjected to the molecular weight reduction processing, and a cross-linking reaction is promoted in the protrusion 201 formed from the resist film R, which hardens the protrusion 201.

In a substrate processing method according to Modification 4, the resist pattern 200 contains a cross-linking agent that promotes cross-linking in response to the application of at least one of thermal energy and energy rays in the molecular weight reduction processing. In this case, the protrusion 201 is hardened by the application of energy rays or thermal energy for performing the molecular weight reduction processing. Therefore, the selectivity (contrast ratio) between the stiffener 220b and the resist pattern 200 is increased, so that it is easy to remove the stiffener 220b in the recess 202 while leaving the resist pattern 200. Further, the application of energy for the molecular weight reduction processing may be effectively used for hardening the protrusion 201 as well.

### (Modification 5)

When a negative type resist pattern is used, the molecular weight reduction processing may be performed for the purpose of improving the etching resistance of a resist pattern, in addition to reducing the number of intermolecular bonds in the stiffener. The term “etching resistance” indicates the difficulty of abrasion and the difficulty of erosion with respect to the resist pattern 200 (protrusion 201). When the etching resistance is improved in the molecular weight reduction processing, the progress of abrasion and erosion of the protrusion 201 is prevented (e.g., the amount of etching is reduced) upon etching after the molecular weight reduction processing, compared to the case where the molecular weight reduction processing is not performed. Examples of the etching after the molecular weight reduction processing include etching for sublimating the stiffener, etching of the wafer W using the resist pattern 200 as a mask, and the like. Further, it is also conceivable that, even when the developing liquid, which is an organic solvent, penetrates a surface layer portion of the resist pattern 200 and softens it during developing, the resulting softened surface layer portion is hardened by the energy applied in the molecular weight reduction processing.

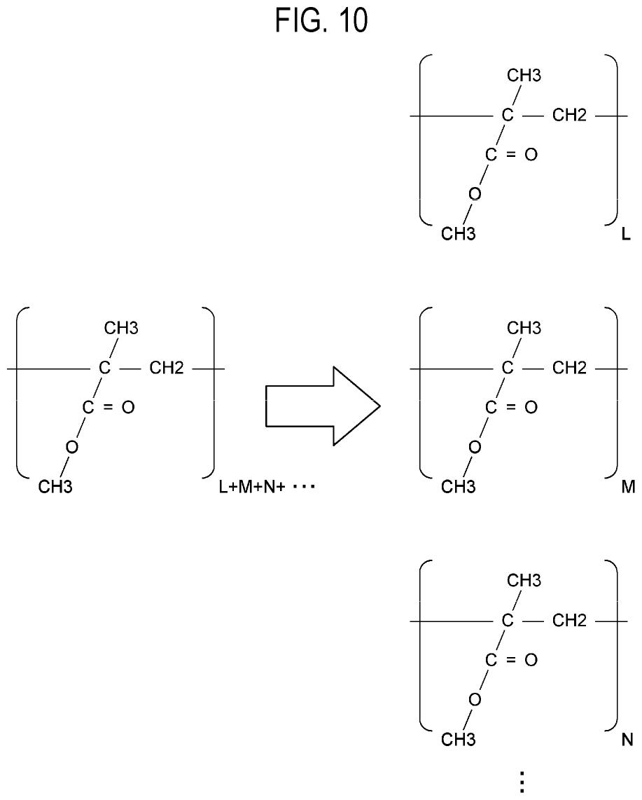

Hereinafter, an example of a substrate processing procedure according to Modification 5 will be described in detail with reference to FIGS. 11A to 13. Also in the substrate processing procedure according to Modification 5, the control device 100 controls the coating/developing apparatus 2 so as to perform the same processing as the substrate processing including the above-described developing procedure (see FIG. 8).

FIG. 11A illustrates the state of exposure. In this exposure, the resist film R formed on the surface Wa of the wafer W is irradiated with (exposed to) energy rays from the light source 221. In the exposure, a mask 222 is arranged between the light source 221 and the wafer W to block the irradiation of energy rays. The mask 222 is provided with an opening 222a corresponding to a portion of the resist film R to be removed. In this case, a region Ra of the resist film R immediately below the opening 222a (a region overlapping the opening 222a when viewing the surface Wa from the direction orthogonal to the surface Wa) is irradiated with energy rays. Further, a region Rb around the region Ra is also irradiated with a slight amount of energy rays due to the diffusivity of light, the dimensional error of the mask 222, or the like. In this case, the region Rb is irradiated with energy rays in an amount sufficient to prevent the corresponding region from being removed during developing.

After the exposure is performed, the control device 100 controls the developing unit U3 so as to supply the developing liquid L1 to the resist film R subjected to the exposure, as in step S02 described above. When the developing liquid L1 is supplied to the resist film R, the region Ra (sufficiently exposed region) irradiated with energy rays for exposure is removed during exposure. Thus, a resist pattern 200A having a plurality of protrusions 201A and a plurality of recesses 202A is formed on the surface Wa, as in the above-described developing procedure. The region Rb, which is irradiated with energy rays for exposure but is not sufficiently irradiated, remains without being removed by the developing liquid L1, and forms the surface (a portion including the surface) of the protrusion 201A. For example, as illustrated in FIG. 11B, the region Rb forms the side surface of the protrusion 201A as well as a part of the upper surface of the protrusion 201A connected to the side surface.

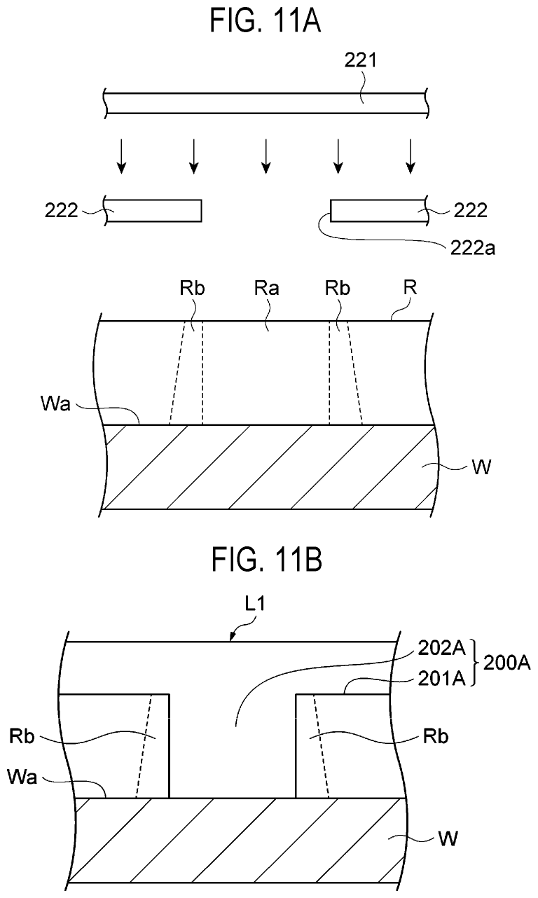

After the resist pattern 200A is formed, the control device 100 sequentially executes the supply of the rinse liquid L2 and the supply of the processing liquid L3 to the surface Wa of the wafer W, as in steps S03 and S04 described above. As illustrated in FIG. 12A, when the rinse liquid L2 is supplied so that the developing liquid L1 in the recess 202A is replaced with the rinse liquid L2, the height of the rinse liquid L2 on the surface Wa may be equal to or greater than the height of the protrusion 201A. That is, the distance between the upper surface of the rinse liquid L2 and the surface Wa may be equal to or greater than the distance between the upper surface of the protrusion 201A and the wafer W. Further, the processing liquid L3 is suppled so that the rinse liquid L2 in the recess 202A is replaced with the processing liquid L3, and before the processing liquid L3 becomes a solid state, the height of the processing liquid L3 on the substrate Wa may be equal to or greater than the height of the protrusion 201A. When the height of the rinse liquid L2 or the processing liquid L3 is equal to or greater than the height of the protrusion 201A, all spaces of the respective recesses 202A in the entire surface Wa of the wafer W are filled with a liquid. Therefore, it is possible to prevent pattern collapse caused by a variation in the amount of a liquid (difference in surface tension) between the adjacent recesses 202A.

After the recess 202A is filled with the processing liquid L3, the control device 100 controls the developing unit U3 so as to form the stiffener 220a in the recess 202A, as in step S05. At this time, the height of the stiffener 220a formed in the recess 202A may be greater than that of the protrusion 201A. The height position of the upper surface of the stiffener 220a (the height position of the upper surface of the processing liquid L3 before formation of the stiffener 220a) may be set to such an extent that energy rays for irradiation in the next processing may reach the protrusion 201A.

After the stiffener 220a is formed in the recess 202A, the control device 100 may control the irradiation unit U5 so that energy rays are applied to the resist pattern 200 (protrusion 201A) and the stiffener 220a, as in step S06. The application of energy rays may reduce the number of intermolecular bonds contained in the stiffener 220a, and may also improve the etching resistance of the region Rb including the surface of the resist pattern 200A (protrusion 201A).

The irradiator 42 illustrated in FIG. 12B is configured to enable both the region Rb of the protrusion 201A and the stiffener 220a to be irradiated with energy rays. The kind of energy rays emitted from the irradiator 42 is preset so as to enable a reduction in the number of intermolecular bonds contained in the stiffener 220a and an improvement in the etching resistance of the region Rb. For example, the kind of energy rays emitted from the irradiator 42 is set so that a chemical reaction different from a chemical reaction caused by irradiation of energy rays for exposure occurs in the resist film R (protrusion 201A). Applying energy rays to the stiffener 220a forms the stiffener (stiffener 220b) subjected to the molecular weight reduction processing, and applying energy rays to the region Rb improves the etching resistance of the region Rb. The irradiator 42 illustrated in FIG. 12B may emit energy rays in an oblique direction with respect to the direction orthogonal to the surface Wa so that the energy rays emitted from a light source also reach a lower portion of the side surface of the protrusion 201A (a portion of the region Rb constituting the side surface).

In addition, the control device 100 may control the irradiation unit U5 or the like so as to apply thermal energy to the stiffener 220a formed in the recess 202A and the resist pattern 200A (protrusion 201A), instead of or in addition to irradiation with energy rays. With the application of thermal energy, the number of intermolecular bonds in the stiffener 220a may be reduced and the etching resistance of the region Rb may be improved.

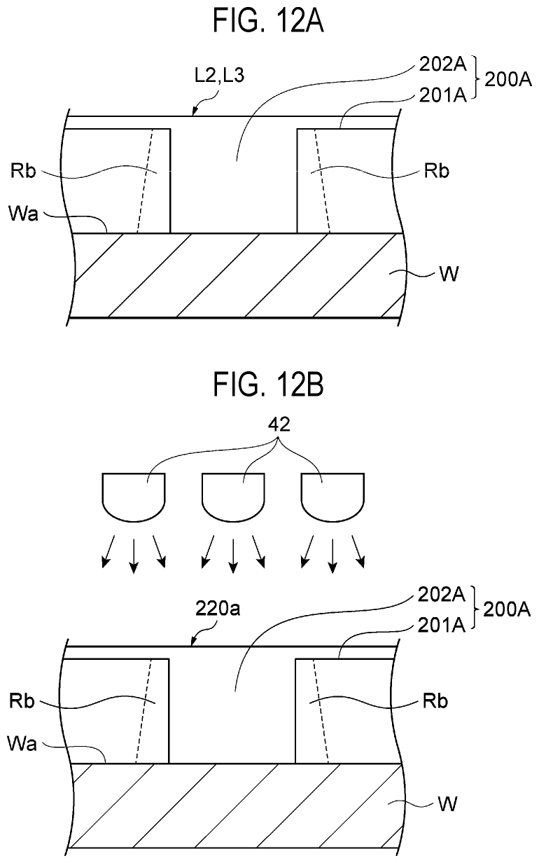

After the stiffener 220b is formed in the recess 202A, the control device 100 controls the plasma processing apparatus 10 or the like so as to remove the stiffener 220b, as in step S08. Thus, as illustrated in FIG. 13, the resist pattern 200A in a state where a liquid and solid are removed from the recess 202A, is formed on the surface Wa. Since the etching resistance of the region Rb is improved, the progress of abrasion and erosion of the region Rb is prevented in the processing of step S08 or in the etching of the wafer W performed after the developing procedure.

In a substrate processing method according to Modification 5 described above, developing includes removing the region Ra of the resist film R, which is exposed by the exposure, to form the resist pattern 200A. This substrate processing method reduces the number of intermolecular bonds contained in the stiffener 220a and improves the etching resistance of the region Rb including the surface of the resist pattern 200A by means of the molecular weight reduction processing. During etching, there is a possibility of a portion of the protrusion slightly irradiated with energy rays for exposure being abraded or eroded, thus causing a deterioration in the accuracy of etching using the resist pattern. On the other hand, with the above method, since the etching resistance of the region Rb is improved, it is possible to prevent a deterioration in the accuracy of etching due to the slightly exposed portion of the protrusion 201A.

### (Modification 6)

A resist pattern including a material that undergoes a dehydration condensation reaction by the application of energy rays or thermal energy may be used. The resist pattern (hereinafter referred to as “resist pattern 200B”) including a material in which a dehydration condensation reaction occurs may contain a metal in order to improve the etching resistance. The resist pattern 200B may have a property that the result of developing for forming the pattern is more susceptible to moisture than the ambient temperature of the wafer W. The resist pattern 200B may be of a negative type, similarly to the resist pattern 200A according to Modification 5.

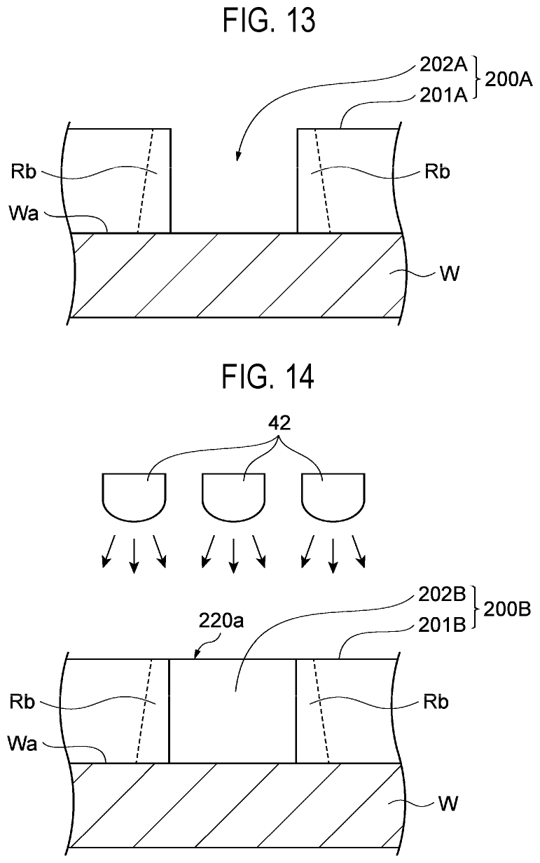

FIG. 14 illustrates the state of the surface Wa on which the resist pattern 200B including a plurality of protrusions 201B and a plurality of recesses 202B is formed, and then the stiffener 220a is formed in the recess 202B. The height of the stiffener 220a formed in the recess 202B may be approximately the same as the height of the protrusion 201B, and the upper surface of the protrusion 201B may be exposed. The control device 100 may control the irradiation unit U5 including the irradiator 42 so that the resist pattern 200B (protrusion 201B) and the stiffener 220a are irradiated with energy rays. When the upper surface of the protrusion 201B is exposed, it is easy to irradiate the protrusion 201B with energy rays.

In addition, the control device 100 may control the irradiation unit U5 or the like so as to apply thermal energy to the resist pattern 200B (protrusion 201B) and the stiffener 220a, instead of or in addition to energy rays. When energy rays or thermal energy is applied to the resist pattern 200B (protrusion 201B), cross-linking by a dehydration condensation is promoted in the resist pattern 200B (protrusion 201B), and as a result, the protrusion 201B is hardened.

In a substrate processing method according to Modification 6 described above, the resist pattern 200B includes a material in which cross-linking by a dehydration condensation reaction is promoted when at least one of thermal energy and energy rays is applied in the molecular weight reduction processing. In this case, the protrusion 201B is hardened by application of energy rays or thermal energy for implementing the molecular weight reduction processing. Therefore, the selectivity (contrast ratio) between the stiffener 220b and the resist pattern 200B is increased, so that it is easy to remove the stiffener 220b in the recess 202B while leaving the resist pattern 200B. Further, the application of energy for the molecular weight reduction processing may be effectively used for hardening the protrusion 201B.

### (Other Modifications)

When replacing a rinse liquid in the recess 202 with a solid-state stiffener, the developing unit U3 may replace the rinse liquid with the stiffener without drying the rinse liquid in the recess 202 (without emptying the recess 202). For example, the developing unit U3 may remove the rinse liquid after supplying a powdered substance including a polymer to the rinse liquid on the surface Wa to precipitate solid matters. Alternatively, the developing unit U3 may solidify the rinse liquid by dissolving a powdered substance including a polymer in the rinse liquid on the surface Wa and drying the rinse liquid in which the substance is dissolved.

The height of the stiffener 220a or 220b formed in the recess 202 may be approximately the same as that of the resist pattern 200 (protrusion 201), or may be smaller than that of the protrusion 201. The height of the stiffener 220a or 220b may be greater than that of the protrusion 201. In this case, the stiffeners 220a (stiffeners 220b) located in the recesses 202 may be connected to each other by a film-shaped stiffener above the protrusion 201. It is only necessary that at least a part of the recess 202 is filled with the stiffener 220a or 220b.

The substrate processing system 1 may be anything so long as it includes a replacement section that replaces a liquid in the recess 202 with a solid-state stiffener, a molecular weight reduction processing section that subjects the stiffener to a molecular weight reduction processing, and a control device capable of controlling these. In the substrate processing system 1, the plasma processing apparatus 10 may be provided in the coating/developing apparatus 2.

The substrate as a processing target is not limited to a semiconductor wafer, and may be, for example, a glass substrate, a mask substrate, a flat panel display (FPD), or the like.

### EXPLANATION OF REFERENCE NUMERALS

1: substrate processing system, 2: coating/developing apparatus, U3: developing unit, U5: irradiation unit, 10: plasma processing apparatus, 200, 200A, 200B: resist pattern, 201, 201A, 201B: protrusion, 202, 202A, 202B: recess, 220a, 220b: stiffener, W: wafer, Wa: surface

1. A substrate processing method comprising:
replacing a liquid in a recess of a substrate having an uneven pattern of a negative type resist including a metal formed on a surface of the substrate with a solid-state stiffener; and
subjecting the substrate to a molecular weight reduction processing that reduces the number of intermolecular bonds contained in the solid-state stiffener while maintaining the solid-state stiffener in a solid state.

2. The substrate processing method of claim 1, wherein the number of intermolecular bonds contained in the solid-state stiffener is reduced up to a level at which the solid-state stiffener is more susceptible to sublimate than the uneven pattern when performing the molecular weight reduction processing.

3. The substrate processing method of claim 1, further comprising: sublimating and removing the solid-state stiffener subjected to the molecular weight reduction processing.

4. The substrate processing method of claim 3, wherein the sublimating and removing the solid-state stiffener includes placing the substrate in a depressurized space to sublimate the solid-state stiffener.

5. The substrate processing method of claim 3, wherein the sublimating and removing the solid-state stiffener includes etching the solid-state stiffener using plasma.

6. The substrate processing method of claim 1, wherein the replacing the liquid with the solid-state stiffener comprises:
supplying a processing liquid to the surface of the substrate to replace the liquid in the recess with the processing liquid; and
drying the processing liquid to form the solid-state stiffener in the recess.

7. The substrate processing method of claim 6, wherein the uneven pattern includes a plurality of recesses, and
wherein the supplying the processing liquid to the surface of the substrate includes starting to supply the processing liquid to the surface of the substrate in a state where the liquid remains in each of the plurality of recesses.

8. The method substrate processing of claim 1, wherein the uneven pattern is a resist pattern formed by developing a resist film subjected to exposure, and
wherein the molecular weight reduction processing includes applying at least one of thermal energy and energy rays to the resist pattern and the solid-state stiffener.

9. The substrate processing method of claim 8, wherein the applying the at least one of the thermal energy and the energy rays causes a dehydration condensation reaction of the resist pattern.

10. The substrate processing method of claim 8, wherein the developing the resist film subjected to exposure includes removing a region of the resist film that is exposed by the exposure to form the resist pattern, and
wherein the molecular weight reduction processing reduces the number of intermolecular bonds contained in the solid-state stiffener and improves etching resistance of a region including a surface of the resist pattern.

11. (canceled)

12. The method substrate processing of claim 1, wherein the solid-state stiffener contains a polymer containing at least one of polymethyl acrylate, polymethacrylic acid, polyvinyl alcohol, an ultraviolet curable resin, and polymethyl methacrylate.

13. A substrate processing apparatus, comprising:
a replacement section configured to replace a liquid in a recess of a substrate having an uneven pattern of a negative type resist including a metal formed on a surface of the substrate with a solid-state stiffener; and
a molecular weight reduction processing section configured to subject the substrate to a molecular weight reduction processing that reduces the number of intermolecular bonds contained in the solid-state stiffener while maintaining the solid-state stiffener in a solid state.
